(19) United States
(12) Patent Application Publication
(10) Pub. No.: US 2013/0074906 A1
(43) Pub. Date: Mar. 28, 2013

(54) APPARATUS FOR CONVERTING THERMAL ENERGY TO ELECTRICAL ENERGY

(71) Applicant: Brad Siskavich, Amherst, NH (US)

(72) Inventor: Brad Siskavich, Amherst, NH (US)

(21) Appl. No.: 13/623,582

(22) Filed: Sep. 20, 2012

Related U.S. Application Data
(60) Provisional application No. 61/536,863, filed on Sep. 20, 2011.

(51) Int. Cl. H01L 31/04

(52) U.S. Cl. CPC H01L 31/0406
USPC 136/246; 136/253

(57) ABSTRACT

Embodiments of an apparatus that can convert energy across a broad spectrum of wavelengths. These embodiments utilize concentrating optics in combination with one or more of an integrated filter, a cooling mechanism, and a high-efficiency low current cell architecture to form efficient and cost-effective TPV devices. During operation, these components reduce the ratio of cell area to emitter area by concentrating the energy the emitter emits, thereby reducing the total cost of materials and promoting efficiency through integrating the filter and cooling mechanism into the device design.

### CROSS-REFERENCE TO RELATED APPLICATIONS

This application claims the benefit of priority under 35 U.S.C. §119(e) to U.S. Provisional Patent Application Ser. No. 61/536,863, entitled “APPARATUS FOR CONVERTING THERMAL ENERGY TO ELECTRICAL ENERGY,” the contents of which is incorporated by reference it its entirety.

### BACKGROUND

1. Technical Field

The subject matter of this disclosure relates to energy conversion and, in particular, to embodiments of an apparatus that convert thermal energy to electrical signals.

2. Description of Related Art

Thermophotovoltaic (TPV) devices convert thermal energy to electric power in accordance with the principles of operation common to solar cells. In particular, an emitter (or “radiator”) emits energy in response to thermal energy that heats the emitter. The thermal energy can arise from a direct source (e.g., through combustion, solar, atomic decay, etc.) or from an indirect source (e.g., industrial waste heat processes). In each case, thermal energy impinges on photoelectric conversion elements, e.g., TPV cells, which convert the energy into electric signals.

Elements of TPV devices include an absorber/emitter material, an energy filtering media, TPV cells for energy conversion, and a cooling mechanism. To successfully commercialize TPV devices (and systems incorporating TPV devices), proposed designs utilize cost-effective TPV cells that can convert as much of the energy the emitter radiates into electrical signals. Energy emitted at less than the TPV cell semiconductor bandgap cannot be converted to electrical energy. This unused energy is often parasitically absorbed by the TPV device as heat, which decreases efficiency of the TPV cell and, ultimately, reduce cost-effective operation.

### SUMMARY

The present disclosure describes embodiments of an apparatus that can convert energy across a broad spectrum of wavelengths. These embodiments utilize concentrating optics in combination with one or more of an integrated filter, a cooling mechanism, and a high-efficiency low current cell architecture to form efficient and cost-effective TPV devices. These components reduce the ratio of cell area to emitter area by concentrating the energy the emitter emit, thereby reducing the total cost of materials and promoting efficiency through integrating the filter and cooling mechanism into the device design.

During operation, embodiments of the proposed apparatus concentrate a large area of energy onto a small TPV cell area via unique construction that enables cost-effective application of the concentrating thermophotovoltaic cells. These embodiments can deploy in high-temperature environments (e.g., a fire, a boiler, an oven, a turbine, a generator, etc.). To harness energy, one or more embodiments can utilize an outer housing made of an absorber/emitter material (AEM), which can be contoured to various shapes, sizes, and form factors (e.g., an elongated, rod design) to fit the environment and/or contour and configuration of the thermal energy source.

### BRIEF DESCRIPTION OF THE DRAWINGS

Reference is now made briefly to the accompanying drawings in which:

FIG. 1 depicts a schematic view of an exemplary embodiment of an apparatus that uses thermal energy to generate electrical signals;

FIG. 2 depicts a perspective view of an exemplary embodiment of an apparatus that uses thermal energy to generate electrical signals;

FIG. 3 depicts a front, cross-section view of the apparatus of FIG. 2;

FIG. 4 depicts a side, cross-section view of the apparatus of FIG. 2;

FIG. 5 depicts a perspective view of an exemplary embodiment of an apparatus that uses thermal energy to generate electrical signals;

FIG. 6 depicts an example of an array of cells that can generate electrical signals in response to electromagnetic radiation;

FIG. 7 depicts a front, cross-section view of a cooling element for use in an apparatus, e.g., the apparatus of FIGS. 1, 2, 3, 4, and 5;

FIG. 8 depicts a front, cross-section view of a cooling element for use in an apparatus, e.g., the apparatus of FIGS. 1, 2, 3, 4, and 5;

FIG. 9 depicts a schematic diagram of an example of a cell for use in an apparatus, e.g., the apparatus of FIGS. 1, 2, 3, 4, and 5;

FIG. 10 depicts a perspective view of an example of a concentration feature for use in an apparatus, e.g., the apparatus of FIGS. 1, 2, 3, 4, and 5; and

FIG. 11 depicts a perspective view of an example of a concentration feature for use in an apparatus, e.g., the apparatus of FIGS. 1, 2, 3, 4, and 5.

Where applicable like reference characters designate identical or corresponding components and units throughout the several views, which are not to scale unless otherwise indicated.

### DETAILED DESCRIPTION

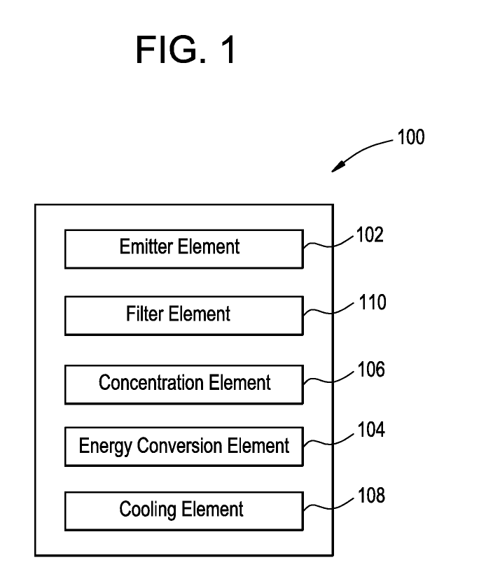

FIG. 1 illustrates a schematic view of an exemplary embodiment of an apparatus 100 that converts radiation (e.g., thermal energy) to electrical signals (e.g., current). The apparatus 100 includes an emitter element 102, an energy conversion element 104, a concentrator element 106, and a cooling element 108. The apparatus 100 also includes a filter element 110, which can reside between the emitter element 102 and the concentrator element 106. At a relatively high level, during operation, the emitter element 102 generates radiation in response to heat and/or other energy. The radiation impinges on the concentrator element 106, which directs the radiation onto the energy conversion element 104. In one example, the energy conversion element 104 converts the radiation into electrical signals. The cooling element 108 circulates a heat transfer medium (also “cooling fluid”) proximate the energy conversion element 104. The heat transfer medium dissipates thermal energy that the energy conversion element 104 does not convert to electrical signals.

Embodiments of the apparatus 100 can harness waste energy, e.g., in the form of heat that results from combustion of fuel. These embodiments find use in various applications, e.g., boilers, furnaces, ovens, and other applications where elevated temperatures prevail and/or where thermal energy is abundant. For example, the apparatus 100 can survive fluids (e.g., gas) at temperatures in excess of 500° C., which may exhaust from a combustion chamber that burns fuel (e.g., wood, coal, natural gas, etc). These heated fluids heat the emitter element 102, which in turn generates electromagnetic radiation that the energy conversion device 104 converts to electrical signals.

Designs for the apparatus 100 utilize components that comport with the environment and/or application in which the apparatus 100 is found. These designs leverage features and aspects of one or more of the elements (e.g., emitter element 102, energy conversion element 104, condenser element 106, and cooling element 108) to convert the thermal energy in the heated fluid to electrical signals. As set forth more below, this disclosure describes features of the apparatus 100 in terms of form factors that may coincide with one or more particular applications. For the combustion applications discussed above, the form factor may conform to the shape of the combustion chamber and/or to the size (e.g., diameter) of pipes, tubes, and conduits that receive exhaust gases from the combustion chamber. However, while indicative of one or more embodiments of the apparatus 100, these form factors can vary in respect to any number of features to attain an output (e.g., electrical signals) that satisfies potential design criteria and/or output thresholds. Such design criteria may require, for example, electrical signals that exhibit certain current levels to re-charge a battery and/or to operate a specified device (e.g., a radio).

The emitter element 102 withstands conditions (e.g., temperature, pressure, humidity, etc.) consistent with the designated application. The emitter element 102 also maximizes the spectrum of electromagnetic radiation generated in response to the thermal energy the emitter element 102 absorbs. Examples of the emitter element 102 act as grey-body and/or black-body emitters, comprising one or more materials that absorb thermal energy and emit electromagnetic radiation. These materials allow implementation of the emitters at temperatures of at least 500° C. or more and, in one particular implementation, at around 1200° C. Emitters of this type can generate electromagnetic radiation having wavelengths, for example, of 900 nm and greater. In one example, the emitter element 102 comprises one or more types of metals (e.g., tungsten, steel, tantalum, etc.), ceramics (e.g., aluminum oxide, silicon carbide, etc.), and composites, as well as compositions, derivations, and combinations thereof. The emitter element 102 may further utilize coatings, paints, and like surface treatments (e.g. erbium oxide, yttrium oxide, silicon carbide) that may improve absorption of heat and/or optimize properties of the emitter element 102 for radiating and dispersing the electromagnetic radiation. In one example, the selection of materials and construction for the emitter element 102 tune the electromagnetic radiation that emanates from the emitter element 102. Such construction may incorporate materials (e.g., tungsten photonic crystals (PhC)) throughout the emitter element 102 to tailor the electromagnetic radiation, e.g., with a cut-off wavelength of 2.3 μm.

Examples of the energy conversion device 104 include integrated circuit and semiconductor devices with structure that generate electricity from electromagnetic radiation. Such devices include thermophotovoltaic cells and/or combination of discrete photovoltaic elements (e.g, diodes) and photovoltaic materials to generate electricity from electromagnetic radiation. These types of devices can comprise a substrate and various layers of materials, the combination of which may cause the device to operate for the purposes herein. This layered structure operates (e.g., to generate electrical signals) in response to electromagnetic radiation over a wide spectrum of wavelengths that are consistent with black-body and grey-body emitter, as discussed above and further below.

Construction of the apparatus 100 positions the concentrator element 106 to receive electromagnetic energy that radiates from the emitter element 102. The construction also directs the electromagnetic energy towards, and in one example, onto the energy conversion device 104. Effective configurations for the concentrator element 106 gather and/or collect the electromagnetic radiation from a large area (e.g., proximate the emitter element 102) and direct the radiation onto a smaller area (e.g., onto the surface of the energy conversion device 102). The ratio of the large area to the smaller area can define a concentration factor for the concentrator element 106. In exemplary devices for use as the concentrator element 106, the concentration factor can be about 2 or greater and, in one example, in a range from about 2 to about 5.

The concentrator element 106 exhibits properties that concentrate the electromagnetic radiation from the emitter element 102, e.g., onto the surface of the energy conversion device 104. These properties can include optical properties and reflective properties, both of which can change the direction and/or focus of the electromagnetic radiation that passes through the concentrator element 106. For optical properties, the concentrator element 106 can form optical components (e.g., lenses) that comprise materials that can transmit electromagnetic radiation of wavelengths contemplated herein. These optical components can have various shapes (e.g., concave, convex, oblate, spheroid, etc.) to match operation of apparatus 100 and/or the constituent components. In one example, the optical components comprise magnesium fluoride, fused quartz, fused silica, and like materials, derivations, combinations, and compositions thereof. For reflective properties, the concentrator element 106 can embody structures with an input opening and an output opening that has an output area that is smaller than an input area of the input opening. The structures can further incorporate wall members with reflective materials and/or coatings to direct the electromagnetic radiation from the input opening to the output opening and, ultimately, onto the surface of the energy conversion device 104. For example, the concentrator element 106 may comprise metals of various types, which form reflective surfaces.

Examples of the filter element 110 form a barrier that allows electromagnetic radiation of a first wavelength (and/or a first range of wavelengths) to pass and that does not allow other electromagnetic radiation of a second wavelength (and/or a second range of wavelengths) to reach the energy conversion device 104. This barrier helps minimize the operating temperature of the apparatus 100 and, in particular, the operating temperature of the energy conversion device 104. Construction of the barrier can be tuned to pass only electromagnetic radiation of wavelengths that will stimulate the energy conversion device 104 to generate electrical signals. In one example, the barrier can reflect other electromagnetic radiation away from the energy conversion device 104. The reflected electromagnetic radiation may be of wavelengths that the energy conversion device 104 can not convert to electrical signals. Exemplary devices for the filter element 110 can embody a plasma filter or like components, that reflects electromagnetic radiation in a direction, e.g., back toward the emitter element 102. Suitable materials for use in the filter element 110 comprise transparent material (e.g. sapphire, fused silica, and magnesium fluoride) with properties that transmit electromagnetic radiation of wavelengths emitted by the emitter element of 102. Such materials may be arranged in one or more layers that reflect radiation of certain wavelengths and allows radiation of certain wavelengths to pass to the energy conversion device 104. For example, the plasma filter may reflect electromagnetic radiation with wavelengths of 1.8 microns to about 10 microns, of 2.3 microns or greater, and/or at least about 1.8 microns or greater.

The cooling element 108 can reduce and maintain the operating temperature of the energy conversion device 104 at levels that permit operation, e.g., at or below about 100° C. In one embodiment, the cooling element 108 is in thermal contact with the energy conversion device 100 to promote the most direct path for heat to dissipate. Examples of the heat transfer medium include water, ethylene glycol, as well as like refrigerants and materials. These materials can circulate through the cooling element 108. For active circulation, the apparatus 100 may couple with a flow generator (e.g., a pump) or other device that can pressurize the material to cause the exchange of material through the cooling element 108. In some applications, the cooling element 108 may employ passive circulation, e.g., when the cooling element 108 incorporates a heat pipe with multiple chambers and integrated construction that can help to rapidly dissipate heat away from the energy conversion device 104.

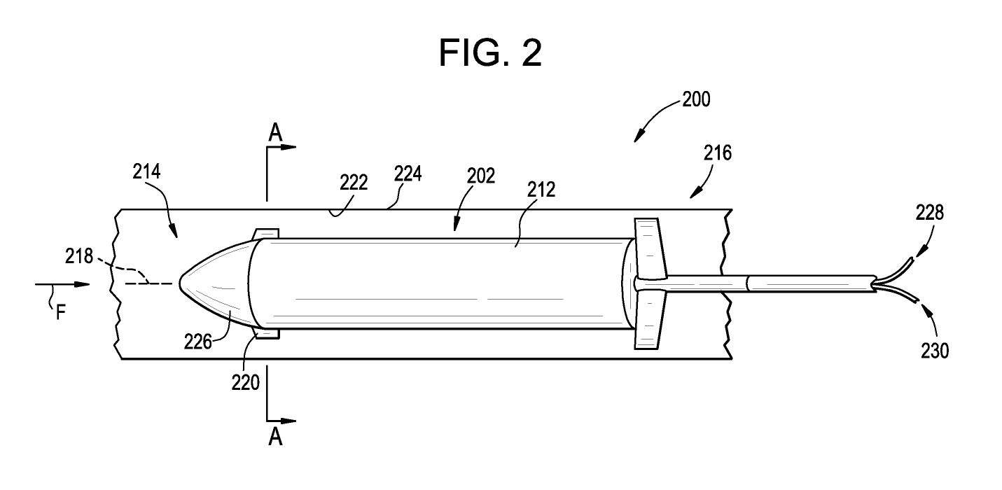

FIGS. 2, 3, and 4 depict another exemplary embodiment of an apparatus 200. As shown in FIG. 2, the emitter element 202 includes an emitter body 212 with a first end 214, a second end 216, and a longitudinal axis 218. One or more support elements 220 extend from the emitter body 212 to engage, in one example, an inner surface 222 of a pipe 224. At the first end 214, the apparatus 200 includes an end cap 226 (also “nose cone 226”), which has a shape to enhance thermal distribution (e.g., to make temperature uniform across the emitter body 212) between the outer surface of the end cap 226 and a flow F of working fluid (e.g., gases) that flows through the pipe 224. The apparatus 200 also has one or more external connections (e.g., a cooling connection 228 and a power connection 230) that secure to the second end 216.

The apparatus 200 may be constructed as a monolithic device, wherein the emitter body 212 and the end cap 226 are formed as a single unitary structure. Such construction may leave the second end 216 open to allow for assembly and installation of components therein. A cover can be placed over the open second end 216 to secure and seal the apparatus 200. In other examples, the apparatus 200 may be assembled from various pieces that fasten together using adhesives, welds, fasteners (e.g., screws and bolts), and like techniques.

The support elements 220 can form fins having an aerodynamic shape (e.g., an airfoil). The fins can form integrally with the emitter body 212 or, in other constructions, the fins can fasten to the outer surface of the emitter body 212 using known fastening techniques. In one embodiment, the fins are sized and configured to fit within the pipe 224. The fit can be loose, i.e., wherein the fins limit movement of the apparatus 200 but the fins do not offer resistance against the inner surface 222 to allow the apparatus 200 to slide through the pipe 224. In other embodiments, the fins can engage the inner surface 222, e.g., via a surface that causes friction and/or exerts a force (e.g., a spring force) against the inner surface 222. Examples of the fins limit conduction, e.g., via embodiments wherein the shape is minimized to limit conduction from the emitter body 212 to the pipe 224.

The emitter body 212 is amenable to various form factors (e.g., shapes and sizes) as might be dictated by the application (e.g., the size and shape of the pipe 224). Examples of the form factor include the elongated cylindrical structure that is shown in FIG. 2. In other examples, the form factor for the emitter body 212 can embody rectangular and cubic features, as well as other multi-sided and non-circular (e.g., ellipsoid) shapes.

External connections 228, 230 allow ingress and egress of cooling fluid (e.g., via cooling connection 228) and electrical signals (e.g., via power connection 230). Examples of the cooling connection 228 can include tubes and conduits that mate with one or more corresponding fittings on the apparatus 200. Examples of the fittings include threaded connectors as well as threaded features (e.g., bores) to receive connectors therein. In the same respect, the power connection 230 can comprise electrical cables (e.g., coaxial cables, multi-wire cables, copper cables, etc.) with one or more electrical connections that couple with an electrical connection on the apparatus 200. For purposes of example, in one implementation the cables can couple with a load (e.g., a motor) and/or a storage unit (e.g., a battery) that the apparatus 200 is to supply with electrical signals. Collectively, the external connections 228, 230 can form a single cable and/or conduit, which can function as one or more of the external connections 228, 230.

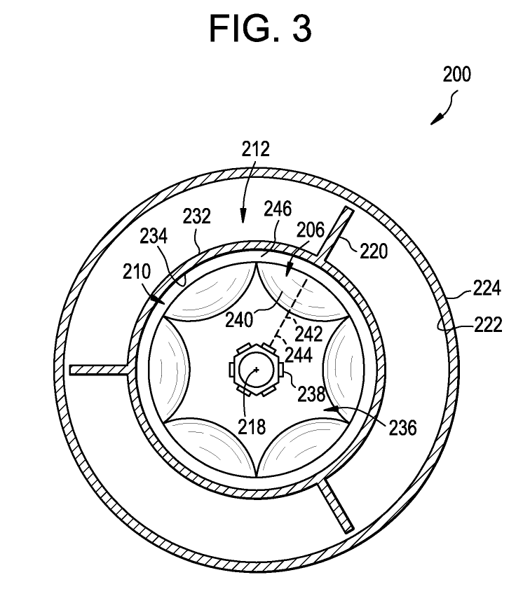

As best shown in FIG. 3, which is a cross-section of the apparatus 200 taken at line A-A of FIG. 2, the emitter body 212 has an outer surface 232 and an inner surface 234 that forms an interior volume 236. The energy conversion device 204 resides in the interior volume 236 in the form of one or more cells 238 disposed circumferentially about the longitudinal axis 218. The concentrator element 206 has a plurality of concentrator features 240 positioned radially outward of the cells 238 and, in one aspect, radially inwardly of the emitter body 212. The concentrator features 240 have an optical axis 242 that aligns with an axis 244 (and/or centerline 244) of the cells 238. This alignment ensures the concentrator features 240 directs electromagnetic energy onto the entire operating surface of the corresponding cell 238. In one embodiment, the filter element 210 includes a material ring 246 disposed radially outwardly of the concentrator element 206, e.g., between the concentrator element 206 and the emitter body 212.

In one embodiment, the emitter body 212 forms a housing to surround, protect, and maintain the components disposed therein. The housing is resistant to high temperatures (e.g., in excess of 500° C.). As set forth above, the housing absorbs heat and/or thermal energy on the outer surface 232, transmits the energy towards the inner surface 234, and disperses the energy as electromagnetic radiation that radiates into the interior volume 236. In other embodiments, construction of the apparatus 200 forms a hermetically-sealed chamber and/or maintains the interior volume 236 at a desired pressure. In one example, the hermetically-sealed chamber is evacuated, e.g., to form a vacuum. The vacuum helps limit interference, often by air or moisture, of electromagnetic radiation in the desired geometric direction. This configuration may improve output, e.g., by reducing energy loss due to conduction or convection. The hermetically-sealed chamber can also can retain various fluids including liquids and gases (e.g., nitrogen, hydrogen, and helium) that afford a desirable environment for energy conversion to occur. Construction of the emitter body 212 can further entail the use of multiple pieces and/or laminated layers of material. For example, this disclosure contemplates structures for the emitter body 212 in which a first inner surface 234 is part of a first material layer and the outer surface 232 is part of a second material layer disposed on the first materials layer.

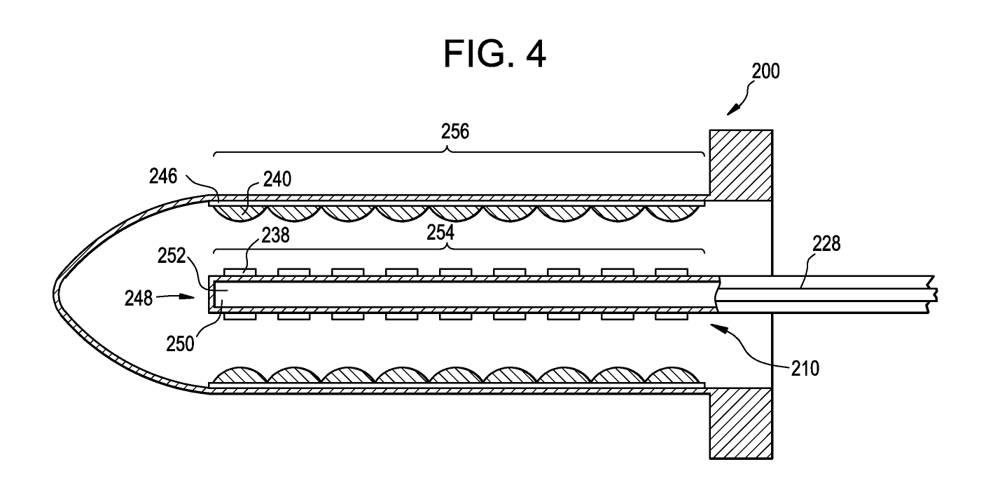

FIG. 4 illustrates a cross-section of the apparatus 200 taken at line B-B of FIG. 2. In the example of FIG. 4, the cooling element 210 has a tubular structure 248 that couples with the cooling connection 228. The tubular structure 248 forms a cooling volume 250 through which a cooling fluid 252 is disposed. In one embodiment, the energy conversion device 204 comprises a first array 254 of the cells 238 that extends along the tubular structure 248. The concentrator element 206 forms a second array 256 of the concentrator features 240, one each corresponding to the number of the cells 238 in the first array 254.

Examples of the tubular structure 248 may contain a fixed amount of the cooling fluid 252. This fixed amount may not circulate out of the apparatus 200. However, in other examples, the cooling fluid 252 can circulate through the tubular structure 248, e.g., under pressure from a cooling fluid supply that is external to the apparatus 200.

Examples of the material ring 246 can form a cylinder that extends at least partially along the longitudinal axis 218. The cylinder permits electromagnetic energy to pass to the concentrator features 240, but may limit transfer of thermal energy, e.g., via conduction and convention between the emitter body 212 and the concentrator features 240 (and other elements and components of the apparatus 200). In one embodiment, the material ring 246 secures directly, by coating or other means, to the inner surface 234. In other examples, the material ring 246 can be supported at various positions by supports that couple the material ring 246 with the cooling element 210 and/or provide mechanical fastening with the emitter body 212. As set forth in more detail below, the material ring 246 can be disposed onto the surface of the cells 238 using known deposition techniques.

While various processes are contemplated, in one example, the material ring 246 can be constructed using various techniques, including via epitaxial lift-off, and incorporated into the apparatus 200. The material ring 246 can be positioned between the emitter body 212 and the concentrator feature 240 and/or disposed on the cells 238. For purposes of positions on the cells 238, the material ring 248 can be grown and/or deposited thereon directly. In one example, bonding material (e.g., a low absorbing yet highly thermally conductive interface material) might be used to secure the material ring 246 to the concentrator features 240 and the cells 238. In one embodiment, the filter component comprises a layer of InPAs nominally doped to 5E¹⁹. The InPAs layer can be grown by MOCVD on an InP substrate.

The material ring 246 may help concentrate the electromagnetic radiation onto the cells 238. For example, the material ring 246 may incorporate geometric shapes (e.g. concave lenses, convex lenses, linear lenses, etc.) that reflect and/or transmit electromagnetic radiation to the concentrator features 240. Such enhancements may reduce the size and shapes of certain components (e.g., the concentrator element 206), thus resulting in lower costs and reducing absorption of electromagnetic radiation that may increase thermal loading of the concentrator component 206. It may be desirable to maintain the components (e.g., the concentrator component 112) inside the housing at lower temperatures (e.g., at or below 100° C.). This feature can be accomplished by limiting the absorption of radiation by the filter component and, where applicable, by any bonding material that secures the filter component to portions of the apparatus 100 such as to the intermediary member 110.

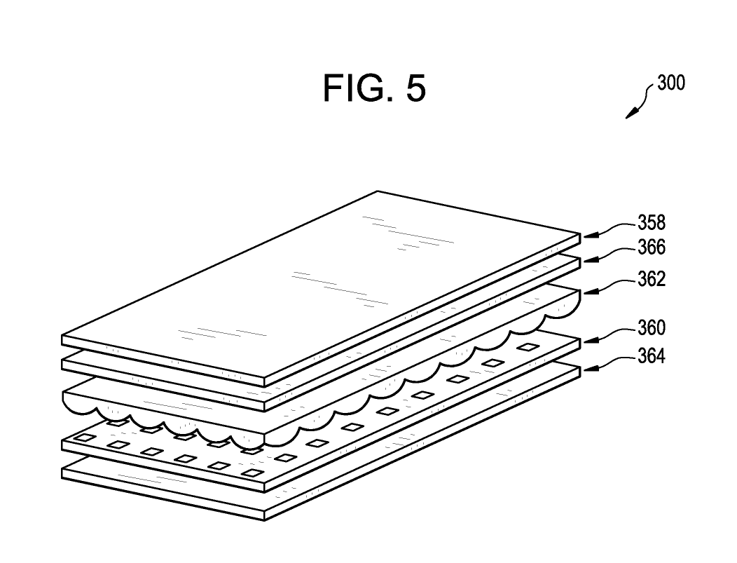

FIG. 5 illustrates a perspective view of another exemplary embodiment of an apparatus 300, which contemplates configurations of the proposed device in the form of a sheet, a panel, or other substantially flat arrangement. In the example of FIG. 5, the apparatus 300 includes a first panel 358 that can emit electromagnetic radiation, a second panel 360 that can convert the electromagnetic radiation into electrical signals, and a third panel 362 that can concentrate the electromagnetic radiation. The apparatus 300 can also include a fourth panel 364 that can dissipate heat, e.g., from the second panel 360. A fifth panel 366 can act as a barrier to filter electromagnetic radiation of certain wavelengths, as set forth herein.

The panels of the apparatus 300 may be affixed together into a single device, e.g., using clamps, frames, and similar fixtures. The types of fixtures may secure to the periphery of the panels, as desired. In other constructions, the individuals panels may be flexible, e.g., if constructed using materials that exhibit physical properties consistent with resilient and/or pliable materials. Embodiments of the apparatus that are constructed in this manner may conform to surfaces that are in and/or susceptible to thermal energy on the order disclosed above. These embodiments may comprise an adhesive or other bonding agent and/or material layer that can withstand the temperatures. Such materials may simplify implementation by providing a simple way to position and secure (e.g., adhere) the apparatus 200 into position.

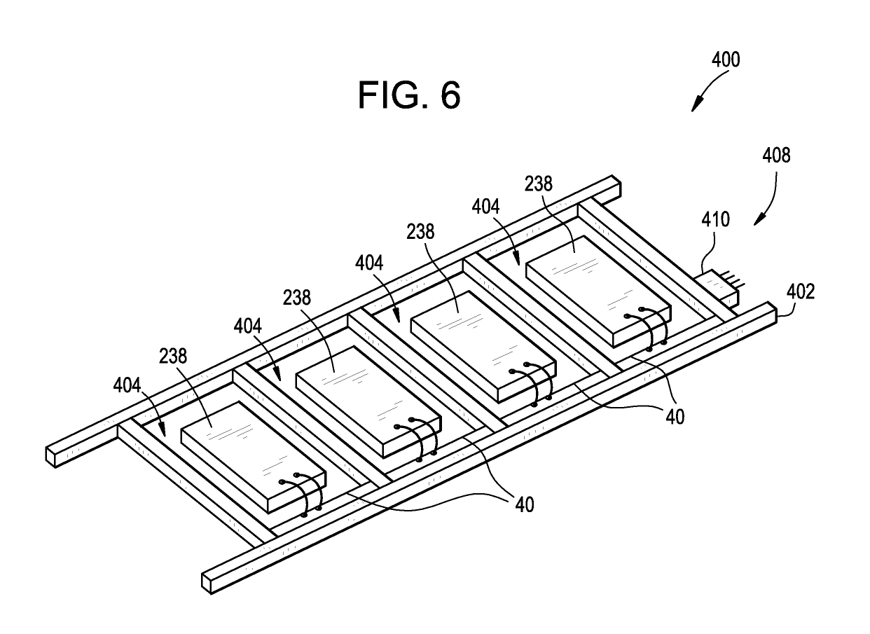

FIG. 6 illustrates one construction of an array 400 that can position, secure, and couple cells (e.g., cells 238 of FIGS. 2, 3, and 4). The array 400 includes a lead frame 402 with one or more cell areas 404 to receive cells 238 therein. The array 400 can also include interconnects 406 that conduct electrical signals from the cells 238 to a terminal end 408. The terminal end 408 may include a connector 410 or similar connective feature, which can allow the array 400 to couple with other arrays 400 that are found in an apparatus (e.g., apparatus 100, 200 of FIGS. 1, 2, 3, and 4) and/or with conductive wiring that connects to the apparatus and with a load. In one embodiment, the lead frame 402 may incorporate one or more supplemental concentrator features (e.g., concentrator features 240 (FIG. 4)) to ensure all radiation is directed to the surface of the cell 238. In other embodiments, the lead frame 402 may likewise incorporate supplemental cooling features that can help to dissipate heat.

Examples of the array 400 can be constructed using traditional semiconductor high-volume assembly technologies. The lead frame 402 can comprise various materials (e.g., metals, ceramics, etc.), which can receive solder, adhesive, and like bonding agents to mechanically secure and interconnect the cells 238 with the lead frame 402 and to one another, e.g., in series. Construction of the array 400 may incorporate one or more carriers comprising, for example, ceramics (e.g., ALN-DBC) onto which the cells 238 mount. The cell areas 402 can be sized to receive the carriers, which may be larger in size as compared to the cells 238. Exemplary construction may require the cells 238 to be soldered to the carriers, which mount to the lead frame 402. Interconnecting leads (e.g., wirebonds) can be added that extend from a first end that couples with interconnects on the cells 238 to a second end that couples with corresponding pads and interconnects on the lead frame 402. In this configuration, the interconnecting leads conduct electrical signals from the cells 238 to the interconnect 406, which can then conduct the electrical signals to the terminal end 408.

At the terminal end 408, embodiments of the array 400 may be outfit with terminals and/or other connective elements that electrically connect the leads (and/or the cells 116) to the exterior of the apparatus. This configuration will permit the electrical signals to couple, e.g., with a load, a plug, an extension cord, and the like. The leads may be electrically isolated from the components of the apparatus including the heat transfer mechanism 108. In one embodiment, the connector 410 may further comprise interface circuitry that can accept a plug or can otherwise permit a peripheral device to be coupled with the array 400.

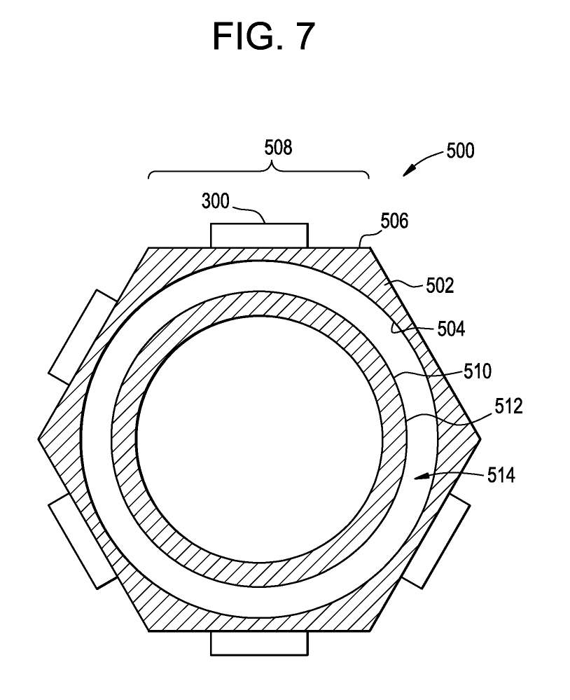

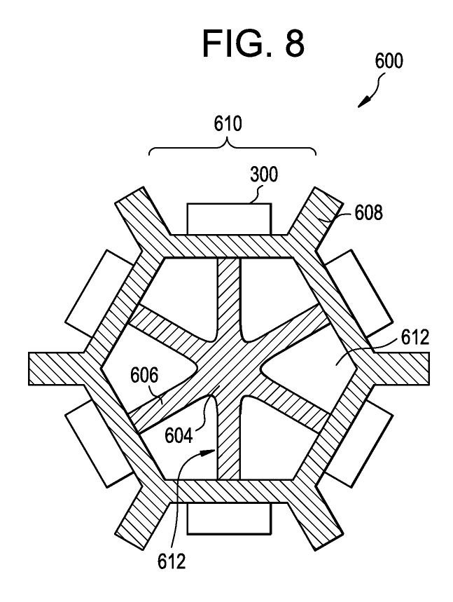

FIGS. 7 and 8 illustrate details to describe the tubular structure in examples of a cooling element 500 (FIG. 7) and a cooling element 600 (FIG. 8). In the example of FIG. 7, the cooling element 500 includes an outer tube 502 with an inner surface 504 and an outer surface 506 that forms one or more mounting surfaces 508, e.g., for the array 500. The cooling element 500 also includes an inner tube 510 that resides inside of the outer tube 502. The inner tube 510 has an outer surface 512 that is spaced apart from the inner surface 504 to form a gap 514. Examples of the outer tube 502 can form a hexagon, although this disclosure contemplates other forms with surfaces (e.g., outer surface 506) that can receive and position the array 500 to receive electromagnetic radiation.

FIG. 8 shows a construction in which the cooling element 600 with a central support feature 602 having a core 604 and one or more extension members 606 that extend therefrom. The cooling element 600 also includes outer ring member 608, disposed radially outwardly from the core 604. The outer ring member 608 includes one or more mounting positions 610 to receive an array, e.g., the array 400 of FIG. 6. This configuration creates one or more channels 612 through which cooling fluid can reside and/or transit the cooling element 600 to dissipate heat from the array 300.

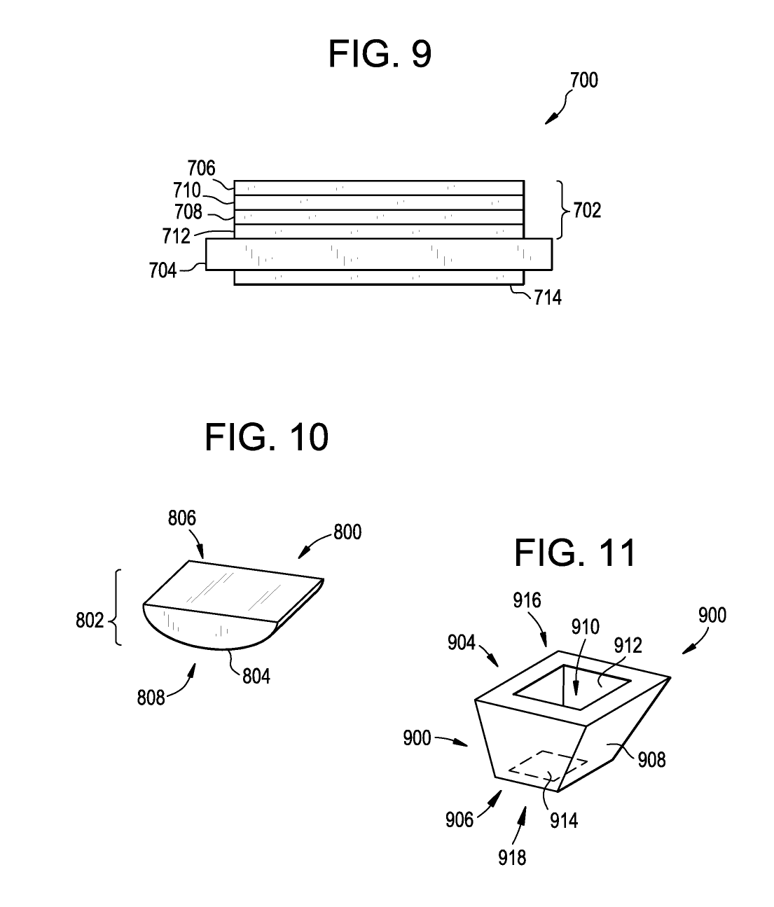

FIG. 9 depicts an example of a cell 700 that can generate electrical signals in response to stimulation by electromagnetic radiation. The cell 700 has a layered structure 702 with a substrate 704 and one or more junction layers (e.g., a first junction 706 and a second junction layer 708). The layered structure 702 further includes one or more auxiliary layers (e.g., a first auxiliary layer 710 and a second auxiliary layer 712) as well as one or more filter layers (e.g., a first filter layer 714). For examples of the cell 700 that include the filter layer(s), exemplary construction of the apparatus 100, 200 may require the cell 70 is positioned to allow the filter layer(s) to receive the electromagnetic radiation before the remainder of the cell 700.

It may also be desirable to maintain a low level of current in the cells 700, while still enabling the cell 70 to convert radiation energy to electrical energy at a high conversion efficiency (e.g., of about 30% or more and, in one example, between about 15% and about 50%). The level of current can be reduced by interconnecting PN junctions on the cell 700 and, more particularly, by connection of the PN junctions in series. In one embodiment, this feature can be achieved by dividing the area of the cell 700 into smaller cell areas and using metallic interconnections to connect adjacent, smaller cells. In another example, as shown in FIG. 8, the cell 700 uses a vertically-stacked multi junction approach where three independent PN junctions are connected in series, e.g., by tunneling diodes. This approach enables the cell 700 to operate at a higher voltage but lower current while maintaining sufficient conversion efficiency when placed under concentration and affords a much simpler method of manufacturing of the cells 700. Moreover, using this approach may enable lower-cost electricity generation and allow for greater flexibility in designing cells (e.g., thermophotvoltaic cells) that are optimized to the apparatus as set forth herein.

In one example, the first junction 706 and the second junction 708 can generate electrical signals in response to, respectively, a first wavelength range and a second wavelength range. The first wavelength range and the second wavelength range can include one or more wavelengths not found in the other. For example, the first wavelength range may include wavelengths from about 900 μm to about 1.6 μm and the second wavelength range may include wavelength from about 1.6 μm to about 2 μm. The extend of the ranges can also be clarified in terms of bandgap, e.g., where the ranges cover 0.52 eV, 0.64 eV, and 0.74 eV.

FIGS. 10 and 11 depict examples of a concentrator feature 800 and a concentrator element 900. The example of FIG. 9 shows the concentrator feature 800 in the form of an optical element 802 with a curvilinear surface 804. The concentrator feature 800 can include a first area 806 and a second area 808 that is smaller than the first area 806. Examples of the concentrator feature 800 can include optics, lens, and like optical facts that can form and direct electromagnetic radiation, e.g., from the first area 806 to the second area 808. In the present example, the curvilinear surface 804 forms a convex curve, which focuses the electromagnetic radiation from a larger area to a much smaller area. This disclosure contemplates other shapes for the curvilinear surface 804 to concentrate electromagnetic radiation, e.g., onto thermophotovoltaic cells.

In the example of FIG. 10, the concentrator feature 900 includes a concentrator body 902 with a top 904 and a bottom 906. The concentrator body 902 is constructed of one or more wall members 908 which couple together to form an interior passage 910 extending from a first opening 912 (at the top 904) to a second opening 914 (at the bottom 906). The concentrator body 902 forms a first area 916 and a second area 918 that is smaller than the first area 916.

The concentrator feature 900 can be made, e.g., of metal, that is formed in the various shapes, and generally reflective and or coated with a reflective coating material at least on the surfaces of the wall members 908 that bound the interior passage 910. The shape of the concentrator feature 900 is selected to direct electromagnetic radiation through the interior passage 910, with the dimensional difference between the first opening 912 and the second opening 914 in the present example useful to collect large amounts of electromagnetic radiation at the top 904 and concentrate the electromagnetic radiation at the bottom 906.

In view of the foregoing, embodiments of the apparatus discussed herein can convert heat and thermal energy to electrical signals, e.g., for re-charging a battery. These embodiments arrange cells (e.g., thermophotovoltaic cells) in combination with concentrator features to provide the cells with electromagnetic radiation in sufficient amounts to generate electrical signals. One or more embodiments can be combined to form a plurality of the apparatus, which can effectively increase output of electrical signals. These systems may be found in various operating environments and used in various applications. These operating environments include one embodiment comprising a singular apparatus in an outdoor fire application, one embodiment comprising a plurality of apparatus aligned linearly within a home or commercial boiler application, one embodiment comprising a circular array of apparatus aligned at an appropriate angle to take advantage of a singular burner as in a cookstove environment, and one embodiment comprising a linear array of apparatus within an industrial heat application such as a smelting furnace, reflow oven.

As used herein, an element or function recited in the singular and proceeded with the word “a” or “an” should be understood as not excluding plural said elements or functions, unless such exclusion is explicitly recited. Furthermore, references to “one embodiment” of the claimed invention should not be interpreted as excluding the existence of additional embodiments that also incorporate the recited features.

This written description uses examples to disclose embodiments of the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. An apparatus, comprising:
an emitter element comprising material that absorbs thermal energy and emits electromagnetic radiation;
an energy conversion device that generates current in response to the electromagnetic radiation; and
a concentrator element disposed in the path of the electromagnetic radiation from the emitter element and the energy conversion device, the concentrator element comprising a concentration feature with a first area proximate the emitter element that receives the electromagnetic radiation and a second area proximate the energy conversion device that is smaller than the first area and through which the electromagnetic radiation radiates onto a surface of the energy conversion device.

2. The apparatus of claim 1, further comprising a cooling element in thermal contact with the energy conversion device.

3. The apparatus of claim 1, further comprising a filter element disposed between the emitter element and the concentrator element, wherein the filter element receives the electromagnetic energy before the concentrator element.

4. The apparatus of claim 1, wherein the emitter element forms an elongated cylindrical body having a first end with an end cap that is aerodynamically shaped and a second end that couples with an external connection.

5. The apparatus of claim 1, further comprising a lead frame that couples a plurality of the energy conversion devices with one anther in series.

6. The apparatus of claim 1, wherein the energy conversion device comprises a thermophotovoltaic cell.

7. The apparatus of claim 1, wherein the energy conversion device comprises a first junction responsive to a first wavelength range and a second junction responsive to a second wavelength range that includes one or more wavelengths not found in the first wavelength range.

8. The apparatus of claim 7, wherein the first wavelength range and the second wavelength range have at least one common wavelength.

9. The apparatus of claim 1, wherein the concentrator element comprises a lens that forms the first area and the second area, and wherein the lens has a curvilinear surface at the second area.

10. The apparatus of claim 1, wherein the concentrator element comprises a wall member that forms an interior passage through which the electromagnetic radiation can pass, and wherein the wall member has a surface that reflects the electromagnetic energy in the interior passage.

11. An apparatus, comprising:
an elongated cylindrical body having a longitudinal axis and forming an interior volume;
an array of energy conversion devices disposed in the interior volume;
a concentrator element disposed radially outwardly of the array and radially inwardly of the elongated cylindrical body, the concentrator element comprising concentrator features that align with the energy conversion devices in the array; and
a filter element disposed between the concentrator element and the elongated cylindrical body.

12. The apparatus of claim 11, further comprising a cooling element coupled with the array, the cooling element comprising a tubular structure that extends along the longitudinal axis.

13. The apparatus of claim 12, wherein the tubular structure comprises an outer tube and an inner tube that resides inside the outer tube, wherein the outer tube comprises an outer surface with one or more mounting surfaces to receive the array of energy conversion devices thereon.

14. The apparatus of claim 13, wherein the tubular structure forms a hexagon.

15. The apparatus of claim 12, wherein the tubular structure comprises an outer ring member forming an interior volume and a central support feature with extension members that separate the interior volume of the outer ring member into a plurality of channels through which the cooling fluid can flow.

16. The apparatus of claim 11, wherein the interior volume forms a hermetically-sealed chamber.

17. The apparatus of claim 16, wherein the hermetically-sealed chamber maintains a vacuum.

18. A apparatus, comprising:
an array of thermophotovoltaic cells;
an emitter body in surrounding relation to the array;
a concentrator element disposed radially inwardly of the emitter body and radially outwardly of the array, the concentrator element comprising one or more concentrator features that align with the thermophotovoltaic cells, the concentrator features receiving the radiation at a first area and emitting the electromagnetic radiation at a second area that is smaller than the first area.

19. The apparatus of claim 18, further comprising a material ring disposed about the concentrator element and proximate the emitter body, the material ring comprising material that prevents electromagnetic radiation of one or more wavelengths from the first area.

20. The apparatus of claim 18, further comprising a lead frame coupled with the thermphotovoltaic cells, the lead frame comprising an interconnect that couples the thermophotovoltaic cells in series.
